(19) United States
(12) Patent Application Publication
(10) Pub. No.: US 2026/0060012 A1
(43) Pub. Date: Feb. 26, 2026

(54) FILM FORMING METHOD, ARTICLE MANUFACTURING METHOD, AND PATTERN FORMING APPARATUS

(71) Applicant: CANON KABUSHIKI KAISHA, Tokyo (JP)

(72) Inventors: YOSUKE MURAKAMI, Tochigi (JP); MASAKI SAITO, Tochigi (JP)

(21) Appl. No.: 19/295,823

(22) Filed: Aug. 11, 2025

(30) Foreign Application Priority Data
Aug. 22, 2024 (JP) 2024-141222

(51) Int. Cl. H01L 21/02; G03F 7/16

(52) U.S. Cl. CPC H01L 21/02318; G03F 7/168; H01L 21/02282

(57) ABSTRACT

A film forming method includes forming a first film to which a first pattern has been transferred by arranging a first curable composition on a substrate and shaping the first curable composition using a first mold having the first pattern, and forming a second film to which a second pattern has been transferred by arranging a second curable composition on the first film and shaping the second curable composition using a second mold having the second pattern.

### BACKGROUND

### Field of the Technology

The present disclosure relates to a film forming method, an article manufacturing method, and a pattern forming apparatus.

### Description of the Related Art

As a method of transferring a pattern of an original onto a substrate, there is known an imprint method. In the imprint method, in a state in which a curable composition is arranged on a substrate and the curable composition and a pattern region of a mold are in contact with each other, the curable composition is filled into a space between the substrate and the pattern region, and is then cured. When filling of the curable composition into the space between the substrate and the pattern region is insufficient, a defect such as a gap may occur in a film or a pattern formed by the curable composition. Therefore, to ensure completion of filling of the curable composition into the space between the substrate and the pattern region, a sufficient filling time is necessary, resulting in a decrease in throughput.

Japanese Patent Laid-Open No. 2018-085419 describes that a gas such as helium is supplied between a substrate and a mold to promote filling of an imprint material into a concave portion of a pattern region of the mold.

### SUMMARY

The present disclosure provides a technique advantageous in promoting filling of a curable composition into a space between a substrate and a pattern region of a mold.

A first aspect of the present disclosure provides a film forming method comprising: forming a first film to which a first pattern has been transferred by arranging a first curable composition on a substrate and shaping the first curable composition using a first mold having the first pattern; and forming a second film to which a second pattern has been transferred by arranging a second curable composition on the first film and shaping the second curable composition using a second mold having the second pattern.

A second aspect of the present disclosure provides an article manufacturing method comprising: forming a first film and a second film on a substrate by a film forming method defined as the first aspect; and obtaining an article by processing the substrate on which the first film and the second film have been formed.

A third aspect of the present disclosure provides a pattern forming apparatus comprising: a coating device configured to apply a curable composition onto a substrate; a first film forming device configured to form a first film to which a first pattern has been transferred, by shaping, using a first mold having the first pattern, the curable composition applied onto the substrate by the coating device; and a second film forming device configured to form a second film to which a second pattern has been transferred, by shaping, using a second mold having the second pattern, the curable composition applied onto the first film of the substrate by the coating device.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view schematically showing the arrangement of a first film forming device that can be used to execute a first step;

FIG. 2 is a view schematically showing the arrangement of a second film forming device that can be used to execute a second step;

FIG. 3 is a view exemplifying the array of a plurality of shot regions of a substrate;

FIGS. 4A to 4C are views schematically showing a first arrangement example of a first mold;

FIGS. 5A to 5C are views schematically showing an example of the arrangement of a second mold;

FIG. 6 is a view schematically showing a second arrangement example of the first mold;

FIG. 7 is a view schematically showing a third arrangement example of the first mold;

FIG. 8 is a view schematically showing a fourth arrangement example of the first mold;

FIG. 9 shows views schematically showing a state in which a droplet of a second curable composition arranged in the second step spreads on a first transfer pattern of a first film formed on the substrate in the first step;

FIG. 10 shows views schematically showing a state in which the second curable composition is filled into a space between the second mold and the first film on the substrate in the second step;

FIG. 11 is a view schematically showing an example in which the first film and a second film are formed on the substrate having unevenness on a surface;

FIGS. 12A and 12B are views schematically showing a state in which a droplet of the second curable composition arranged in the second step spreads in a case where the first transfer pattern of the first film includes a rectangular grid;

FIG. 13 is a flowchart illustrating the procedure of a film forming method according to an embodiment;

FIG. 14 is a flowchart illustrating the procedure of the first step;

FIG. 15 is a flowchart illustrating the procedure of the second step;

FIGS. 16A to 16H are views schematically showing the film forming method according to the embodiment;

FIG. 17 is a view showing an example of the arrangement of a pattern forming apparatus according to the embodiment; and

FIGS. 18A to 18G are views schematically showing an article manufacturing method according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes. Positioning means controlling the position and/or posture. Alignment can include controlling the position and/or posture of at least one of a substrate and a mold such that the alignment error (overlay error) between the substrate or a shot region thereof and a pattern region of the mold decreases. In addition, alignment can include control to correct or change the shape of at least one of the substrate or the shot region thereof and the pattern region of the mold.

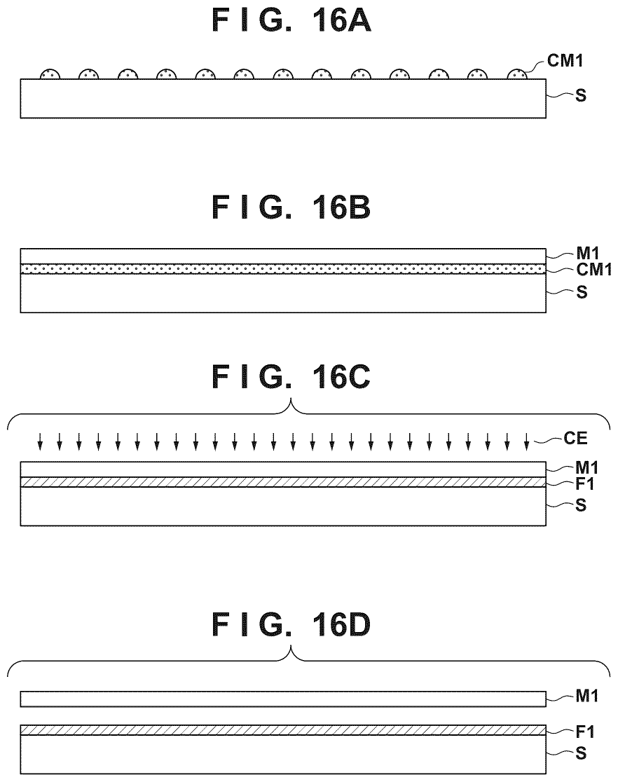

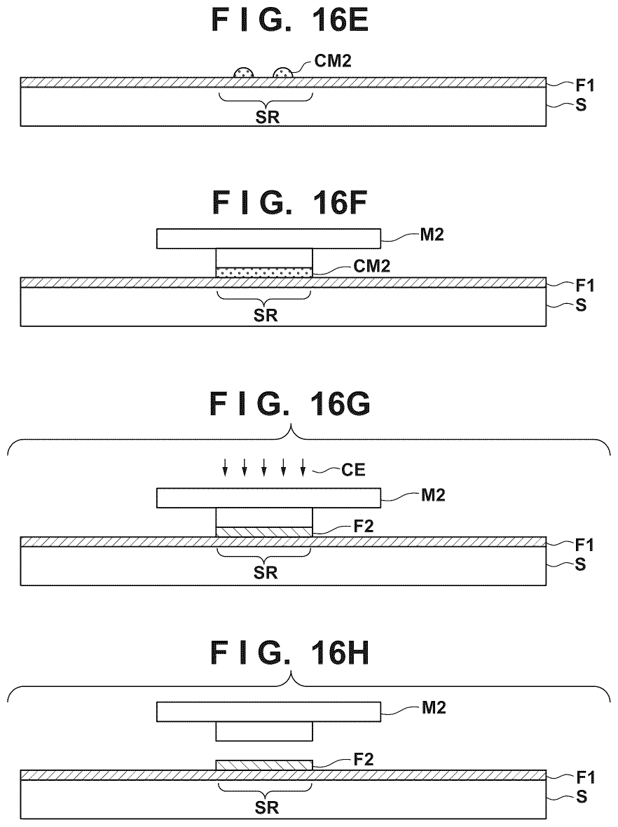

FIGS. 16A to 16H schematically show a film forming method according to an embodiment. The film forming method according to the embodiment includes a first step schematically shown in FIGS. 16A to 16D and a second step schematically shown in FIGS. 16E to 16H. The first step is a step of forming a first film F1 to which a first pattern has been transferred by arranging a first curable composition CM1 on a substrate S and shaping the first curable composition CM1 using a first mold M1 having the first pattern. The second step is a step of forming a second film F2 to which a second pattern has been transferred by arranging a second curable composition CM2 on the first film F1 and shaping the second curable composition CM2 using a second mold M2 having the second pattern.

The curable compositions CM1 and CM2 may be the same material or materials different from each other. The first curable composition CM1 and the second curable composition CM2 are materials to be cured by receiving curing energy CE. As the curing energy CE, an electromagnetic wave, heat, or the like can be used. The electromagnetic wave can be, for example, light selected from the wavelength range of 10 nm (inclusive) to 1 mm (inclusive), such as infrared rays, visible light, or ultraviolet light. The curable compositions CM1 and CM2 can be compositions cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The curable composition CM1 or CM2 can be arranged on the substrate in the form of droplets or in the form of an island or film formed by connecting a plurality of droplets. Alternatively, the curable composition CM1 or CM2 may be supplied onto the substrate in the form of a film by a spin coater or a slit coater. The viscosity (the viscosity at 25° C.) of the curable composition CM1 or CM2 can be, for example, from 1 mPa·s (inclusive) to 100 mPa·s (inclusive). As the material of the substrate S, for example, glass, a ceramic, a metal, a semiconductor (Si, GaN, SiC, or the like), a resin, or the like can be used. A member made of a material different from the substrate S may be provided on the surface of the substrate S, as needed. The substrate includes, for example, a silicon wafer, a compound semiconductor wafer, or silica glass.

The film forming method schematically shown in FIGS. 16A to 16H will be described in more detail below. As shown in FIG. 16A, the first curable composition CM1 can be arranged on the substrate S. The first curable composition CM1 can be arranged on the substrate S in the form of a plurality of droplets apart from each other. The substrate S may have a plurality of shot regions (including a region to become a shot region thereafter), and the first curable composition CM1 can be arranged in all the plurality of shot regions.

Next, as shown in FIG. 16B, the first mold M1 can be arranged so that the first mold M1 having a first pattern (not shown) contacts the first curable composition CM1 on the plurality of shot regions of the substrate S. This can be done by driving at least one of the first mold M1 and the substrate S. This can start filling of the first curable composition CM1 into the space between the substrate S and the first mold M1, thereby forming a liquid film of the first curable composition CM1 between the first mold M1 and the plurality of shot regions of the substrate S. Before bringing the first mold M1 into contact with the first curable composition CM1 on the substrate S, a filling promotion gas may be provided to the space between the substrate S and the first mold M1. The filling promotion gas can include at least one of, for example, helium gas, nitrogen gas, and a condensable gas (for example, pentafluoropropane (PFP)).

Next, as shown in FIG. 16C, the first curable composition CM1 is cured by giving the curing energy CE to the first curable composition CM1 between the first mold M1 and the plurality of shot regions of the substrate S. This obtains the first film F1 on which the first pattern has been transferred by shaping the first curable composition CM1 using the first mold M1 having the first pattern.

Next, as shown in FIG. 16D, the first mold M1 is separated from the first film F1. This can be done by driving at least one of the first mold M1 and the substrate S.

Next, as shown in FIG. 16E, the second curable composition CM2 can be arranged on a shot region SR of the substrate S. For example, the second curable composition CM2 can be arranged, as a liquid of a plurality of droplets, on the shot region SR of the substrate S.

Next, as shown in FIG. 16F, the second mold M2 can be arranged so that the second mold M2 having a second pattern (not shown) contacts the second curable composition CM2 on the one shot region SR of the substrate S. This can be done by driving at least one of the second mold M2 and the substrate S. This can start filling of the second curable composition CM2 into the space between the substrate S (the first film F1 thereon) and the second mold M2, thereby forming a liquid film of the second curable composition CM2 between the second mold M2 and the shot region SR of the substrate S.

In this state, a groove to which the first pattern of the first mold M1 has been transferred is formed on the surface of the first film F1 in the first step. Thus, filling of the second curable composition CM2 into the space between the substrate S (the first film F1 thereon) and the second mold M2 is promoted by the groove. That is, the first film F1 having the groove to which the first pattern of the first mold M1 has been transferred functions as a filling promotion film for promoting filling of the second curable composition in the second step. Before bringing the second mold M2 into contact with the second curable composition CM2 on the first film F1 on the substrate S, a filling promotion gas may be provided to the space between the first film F1 and the second mold M2. The filling promotion gas can include at least one of, for example, helium gas, nitrogen gas, and a condensable gas (for example, pentafluoropropane (PFP)).

Next, as shown in FIG. 16G, the second curable composition CM2 is cured by giving the curing energy CE to the second curable composition CM2 between the second mold M2 and the first film F1 on the shot region SR of the substrate S. This obtains the second film F2 on which the second pattern has been transferred by shaping the second curable composition CM2 using the second mold M2 having the second pattern.

Next, as shown in FIG. 16H, the second mold M2 is separated from the second film F2. This can be done by driving at least one of the second mold M2 and the substrate S. The second step shown in FIGS. 16E to 16H can be executed for the plurality of shot regions SR of the substrate S.

In the first step shown in FIGS. 16A to 16D, the first pattern of the first mold M1 can collectively be transferred to the first curable composition CM1 spreading to cover the entire region including the plurality of shot regions SR of the substrate S. On the other hand, in the second step shown in FIGS. 16E to 16H, the second pattern of the second mold M2 can be transferred to the second curable composition CM2 for each shot region SR as a unit.

In this embodiment, the first step is added to conventional steps. Since, however, the first step is collectively executed for the plurality of shot regions of the substrate S, a delay caused by this processing is minimal. On the other hand, if the filling time for each shot region is shortened by Δt by the first film F1, the time required to transfer the second pattern of the second mold M2 to the plurality of shot regions of one substrate is shortened by Δt×N (N represents the number of shot regions).

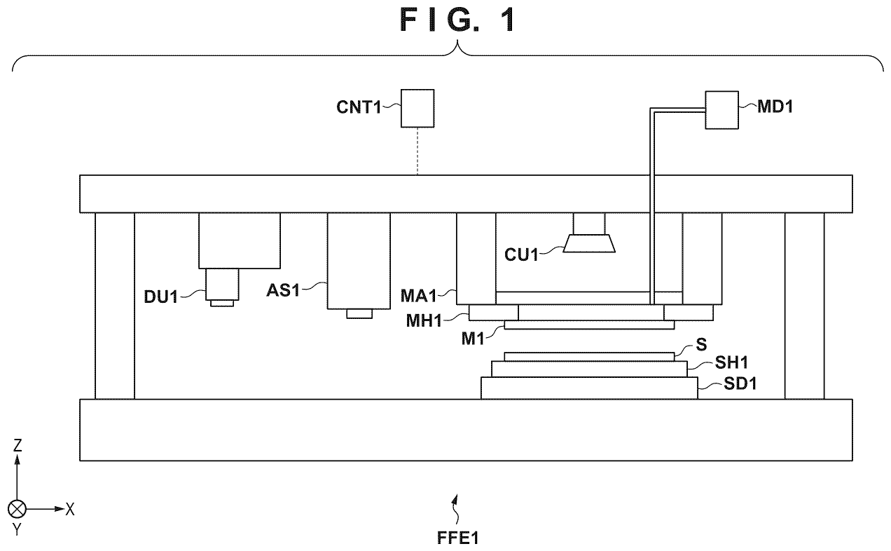

FIG. 1 schematically shows the arrangement of a first film forming device FFE1 that can be used to execute the first step. The first film forming device FFE1 can include a substrate holder SHE that holds the substrate S, and a substrate driving mechanism SD1 that drives the substrate S by driving the substrate holder SH1. The substrate driving mechanism SD1 can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis).

The first film forming device FFE1 can also include a mold holder MH1 that holds the first mold M1, and a mold driving mechanism MA1 that drives the first mold M1 by driving the mold holder MH1. The mold driving mechanism MA1 can be configured to drive the first mold M1 with respect to a plurality of axes (for example, three axes including the Z-axis, θX-axis, and θY-axis, and preferably six axes including the X-axis, Y-axis, Z-axis, θX-axis, θY-axis, and θZ-axis).

The first film forming device FFE1 can also include a shape controller MD1 that controls the shape related to the Z-axis of the first mold M1 held by the mold holder MH1. For example, the shape controller MD1 can control the shape related to the Z-axis of the first mold M1 by adjusting the pressure on the rear surface (the surface on the opposite side of the surface including the pattern region contacting the first curable composition) of the first mold M1 held by the mold holder MH1. When bringing the pattern region of the first mold M1 into contact with the first curable composition on the substrate S, the shape of the first mold M1 can normally be controlled by the shape controller MD1 so as to be convex downward.

The first film forming device FFE1 can also include a curing unit CU1 that cures the first curable composition by irradiating, with curing energy, the first curable composition filled into the space between the first mold M1 and the plurality of shot regions of the substrate S. In addition, the first film forming device FFE1 can include a dispenser DU1 that arranges the first curable composition on the plurality of shot regions of the substrate S. Note that the substrate S with the first curable composition arranged on the plurality of shot regions may be loaded or supplied into the first film forming device FFE1. In this case, the dispenser DU1 need not be provided. The first film forming device FFE1 can include an alignment scope AS1. The alignment scope AS1 can be used to detect the position of an alignment mark provided on the substrate S.

The first film forming device FFE1 can further include a controller CNT1 that controls the substrate holder SH1, the substrate driving mechanism SD1, the mold holder MH1, the mold driving mechanism MA1, the curing unit CU1, the dispenser DU1, the alignment scope AS1, the shape controller MD1, and the like. The controller CNT1 can be formed by, for example, a PLD (an abbreviation of Programmable Logic Device) such as an FPGA (an abbreviation of Field Programmable Gate Array), an ASIC (an abbreviation of Application Specific Integrated Circuit), a general-purpose or dedicated computer installed with a program, or a combination of all or some of them.

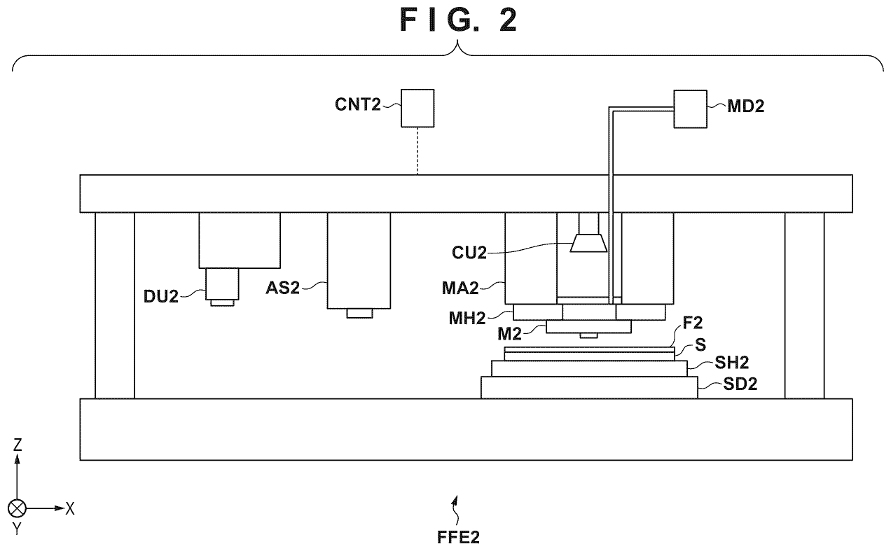

FIG. 2 schematically shows the arrangement of a second film forming device FFE2 that can be used to execute the second step. The second film forming device FFE2 can include a substrate holder SH2 that holds the substrate S on which the first film F1 has been formed, and a substrate driving mechanism SD2 that drives the substrate S by driving the substrate holder SH2. The substrate driving mechanism SD2 can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis).

The second film forming device FFE2 can also include a mold holder MH2 that holds the second mold M2, and a mold driving mechanism MA2 that drives the second mold M2 by driving the mold holder MH2. The mold driving mechanism MA2 can be configured to drive the second mold M2 with respect to a plurality of axes (for example, three axes including the Z-axis, θX-axis, and θY-axis, and preferably six axes including the X-axis, Y-axis, Z-axis, θX-axis, θY-axis, and θZ-axis).

The second film forming device FFE2 can also include a shape controller MD2 that controls the shape related to the Z-axis of the second mold M2 held by the mold holder MH2. For example, the shape controller MD2 can control the shape related to the Z-axis of the second mold M2 by adjusting the pressure on the rear surface (the surface on the opposite side of the surface including the pattern region contacting the second curable composition) of the second mold M2 held by the mold holder MH2. When bringing the pattern region of the second mold M2 into contact with the second curable composition on the substrate S, the shape of the second mold M2 can normally be controlled by the shape controller MD2 so as to be convex downward.

The second film forming device FFE2 can also include a curing unit CU2 that cures the second curable composition by irradiating, with curing energy, the second curable composition filled into the space between the second mold M2 and the shot region of the substrate S. In addition, the second film forming device FFE2 can include a dispenser DU2 that arranges the second curable composition on the shot region of the substrate S. Note that the substrate S with the second curable composition arranged on the plurality of shot regions may be loaded or supplied into the second film forming device FFE2. In this case, the dispenser DU2 need not be provided. The second film forming device FFE2 can include an alignment scope AS2. The alignment scope AS2 can be used to detect the position of an alignment mark provided on the substrate S.

The second film forming device FFE2 can further include a controller CNT2 that controls the substrate holder SH2, the substrate driving mechanism SD2, the mold holder MH2, the mold driving mechanism MA2, the curing unit CU2, the dispenser DU2, the alignment scope AS2, the shape controller MD2, and the like. The controller CNT2 can be formed by, for example, a PLD (an abbreviation of Programmable Logic Device) such as an FPGA (an abbreviation of Field Programmable Gate Array), an ASIC (an abbreviation of Application Specific Integrated Circuit), a general-purpose or dedicated computer installed with a program, or a combination of all or some of them.

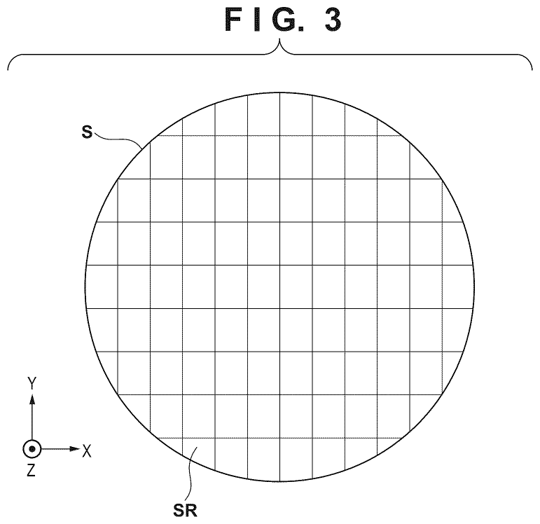

FIG. 3 exemplifies the array of the plurality of shot regions SR of the substrate S. Note that in FIG. 3, reference symbol SR denotes one shot region for the sake of simplicity. The substrate S can include a rectangular shot region (full field) and a shot region (partial field) where a part of the shape is defined by an arc along the edge of the substrate S.

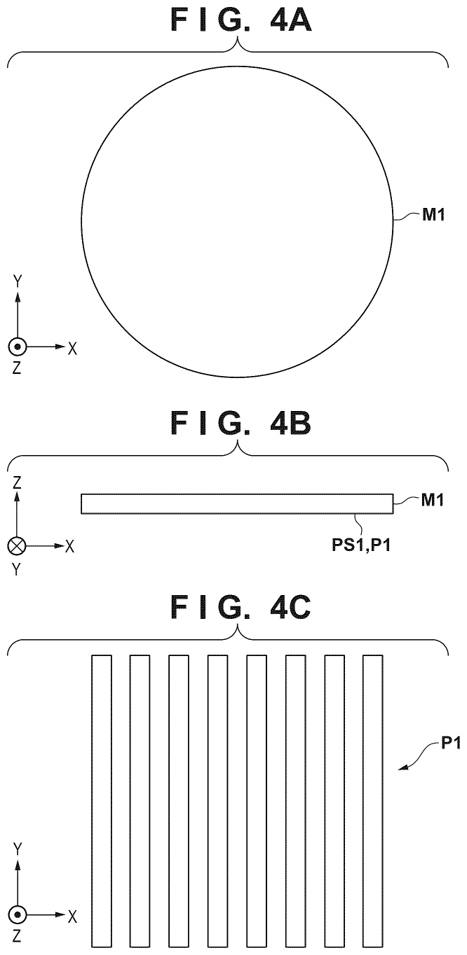

FIGS. 4A to 4C schematically show a first arrangement example of the first mold M1. FIGS. 4A and 4B are respectively a schematic plan view and a schematic side view of the first mold M1. The first mold M1 includes a pattern region PS1 (first pattern region) with a first pattern P1. The pattern region PS1 is a region that contacts the first curable composition CM1 in the first step, and includes a region facing the plurality of shot regions of the substrate S. FIG. 4C is a view obtained by enlarging a portion of the pattern region PS1 in an example. As exemplified in FIG. 4C, the first pattern P1 may be a line-and-space pattern, and the width of each of the line and the space of the line-and-space pattern may be smaller than the radius of each droplet of the first curable composition CM1 arranged on the substrate S. The width of each of the line and the space of the line-and-space pattern can be, for example, 10 μm or less. Furthermore, the width of each of the line and the space of the line-and-space pattern can be, for example, 1 μm or more. The first pattern P1 may be, for example, another pattern such as a grid pattern.

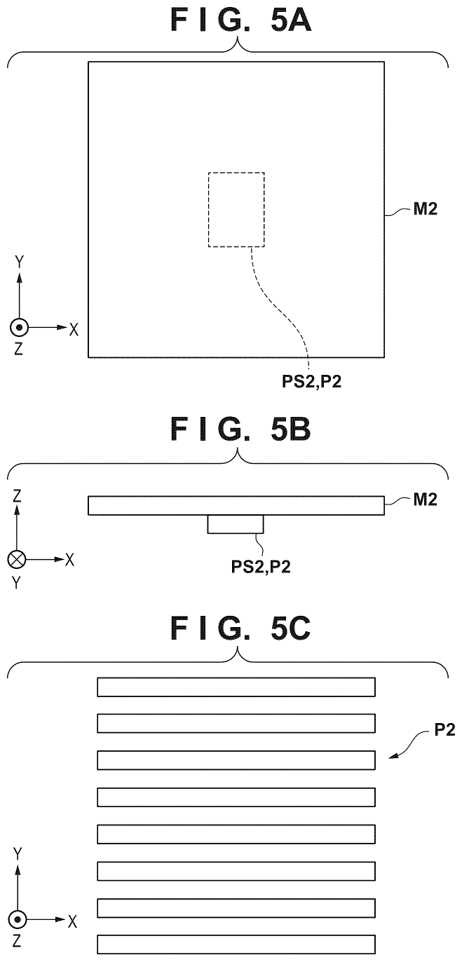

FIGS. 5A to 5C schematically show an example of the arrangement of the second mold M2. FIGS. 5A and 5B are respectively a schematic plan view and a schematic side view of the second mold M2. The second mold M2 includes a pattern region PS2 (second pattern region) with a second pattern P2. The pattern region PS2 is a region that contacts the second curable composition CM2 in the second step, and includes a region facing one shot region of the substrate S. FIG. 5C is a view obtained by enlarging a portion of the pattern region PS2 in an example. As exemplified in FIG. 5C, the second pattern P2 can be a line-and-space pattern but may be another pattern.

The second mold M2 according to the arrangement example is suitable for transferring the second pattern P2 onto the first film F1 formed using the first mold M1 according to the first arrangement example. The first film F1 formed using the first mold M1 can include a first feature (for example, a groove) formed by transferring the first pattern P1. The second pattern P2 can include a second feature (for example, a groove) extending in a direction crossing a direction in which the first feature extends in a state in which the second mold M2 is arranged on the second curable composition CM2. For example, the second feature may extend in a direction orthogonal to the direction in which the first feature extends in the state in which the second mold M2 is arranged on the second curable composition CM2.

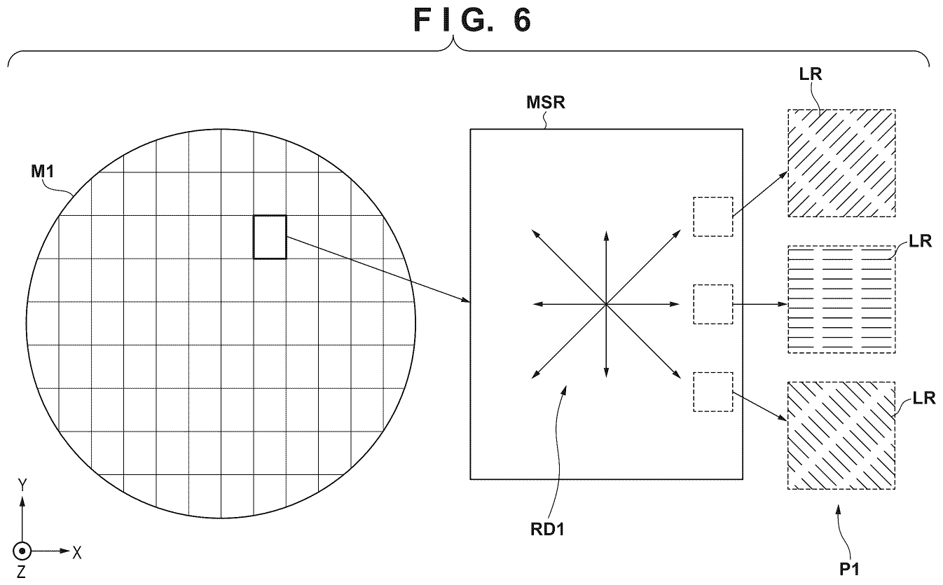

FIG. 6 schematically shows a second arrangement example of the first mold M1. The first mold M1 of the second arrangement example includes a plurality of regions MSR respectively corresponding to the plurality of shot regions SR of the substrate S, each region MSR includes a plurality of lines LR as the first pattern P1, and the plurality of lines LR can coincide with radial directions RD1 in each region MSR. The first film F1 formed using the first mold M1 includes a plurality of grooves formed by transferring the plurality of lines LR of the first pattern P1, and directions in which the plurality of grooves extend can coincide with the radial directions in each shot region SR.

In an example, the plurality of lines LR provided in each region MSR of the first mold M1 can include the lines LR shorter than 1/2, 1/5, or 1/10 of the length of the short side of each region MSR (in other words, the length of the short side of each shot region of the substrate S). In this case, the plurality of grooves of the first film F1 formed using the first mold M1 can include grooves shorter than 1/2, 1/5, or 1/10 of the length of the short side of the shot region SR.

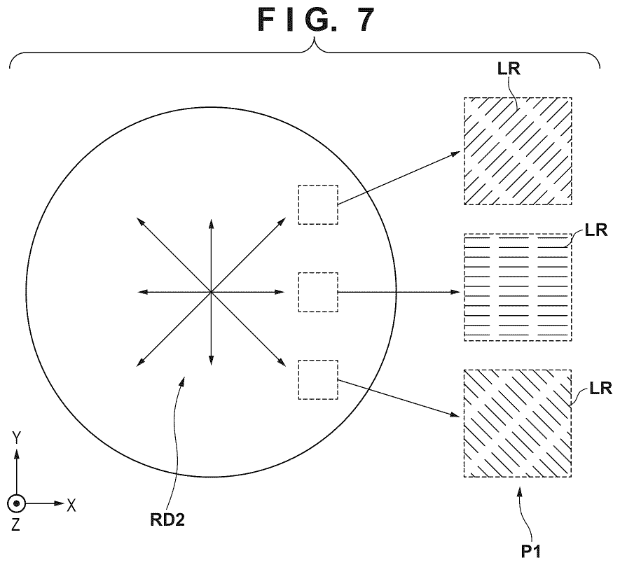

FIG. 7 schematically shows a third arrangement example of the first mold M1. The first mold M1 of the third arrangement example includes the plurality of lines LR as the first pattern P1, and the plurality of lines LR can coincide with radial directions RD2 on the substrate S. The first film F1 formed using the first mold M1 includes a plurality of grooves formed by transferring the plurality of lines LR of the first pattern P1, and directions in which the plurality of grooves extend can coincide with the radial directions on the substrate S.

In an example, the plurality of lines LR provided on the first mold M1 can include the lines LR shorter than 1/5, 1/10, or 1/100 of the radius of the pattern region PS1 of the first mold M1. In this case, the plurality of grooves of the first film F1 formed using the first mold M1 can include grooves shorter than 1/5, 1/10, or 1/100 of the radius of the substrate S.

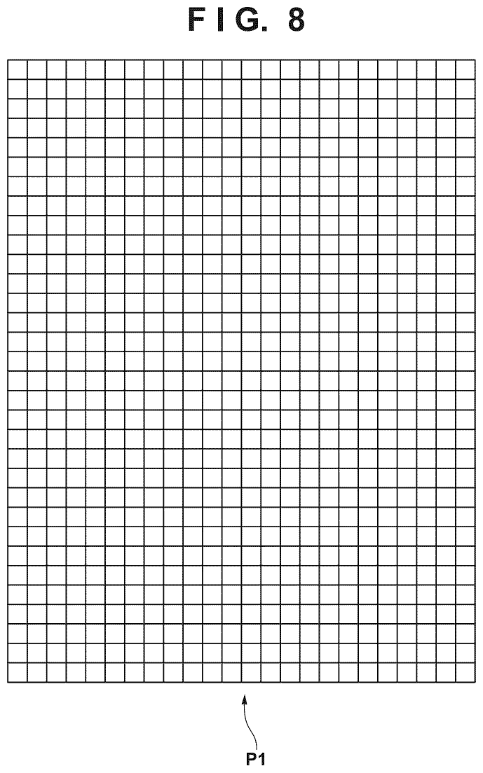

FIG. 8 schematically shows a fourth arrangement example of the first mold M1. The first mold M1 of the fourth arrangement example can include a rectangular grid as the first pattern P1. The first film F1 formed using the first mold M1 can include a rectangular grid formed by transferring the rectangular grid of the first pattern P1. The rectangular grid as the first pattern P1 may be separated between the plurality of regions respectively corresponding to the plurality of shot regions, or may spread over the entire pattern region PS1 of the first mold M1 without being separated between the plurality of regions.

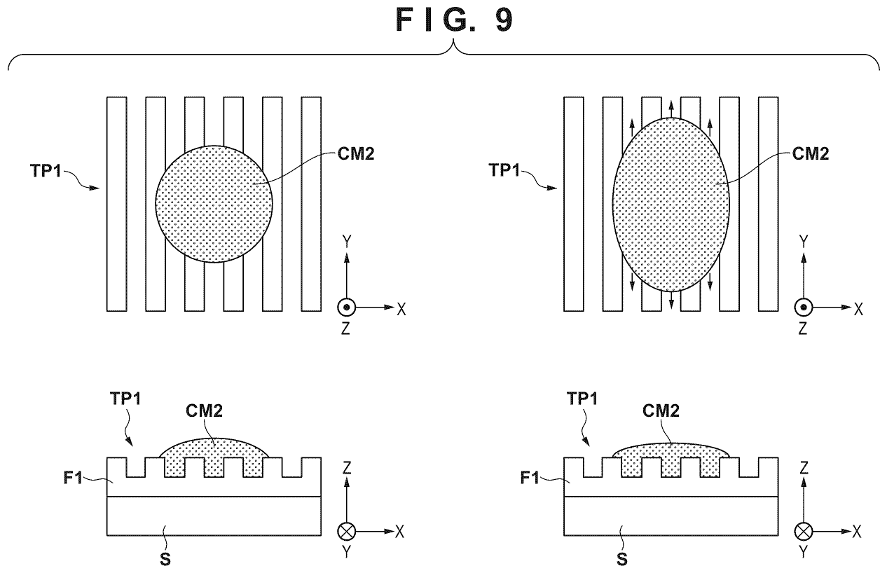

FIG. 9 schematically shows a state in which a droplet of the second curable composition CM2 arranged in the second step spreads on a first transfer pattern TP1 of the first film F1 formed on the substrate S in the first step. The first transfer pattern TP1 is a pattern obtained by transferring the first pattern P1. The droplet of the second curable composition CM2 tends to spread in a direction in which the lines and spaces forming the line-and-space pattern of the first transfer pattern TP1 extend. This can contribute to promotion of filling of the second curable composition CM2 in the direction in which the lines and spaces extend.

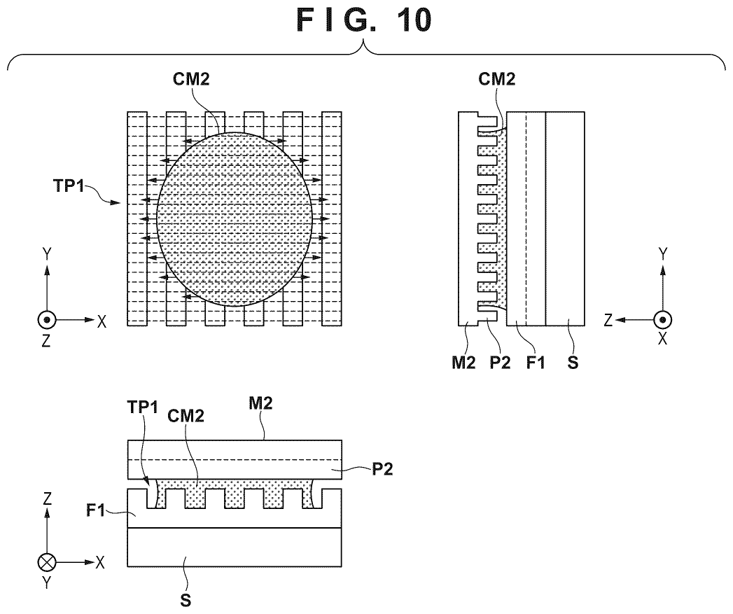

FIG. 10 schematically shows a state in which the second curable composition CM2 is filled into a space between the second mold M2 and the first film F1 on the substrate S in the second step. In the example shown in FIG. 10, a direction (Y direction) in which the feature (each element of the line-and-space pattern) forming the first transfer pattern TP1 of the first film F1 extends and a direction (X direction) in which the feature of the second pattern of the second mold M2 extends cross each other or are orthogonal to each other. Therefore, the second curable composition CM2 tends to spread in the two directions (X direction and Y direction), thereby promoting filling of the second curable composition CM2 into the space between the second mold M2 and the first film F1 on the substrate S. Therefore, the time taken to transfer the second pattern P2 of the second mold M2 onto each shot region of the substrate S can be shortened.

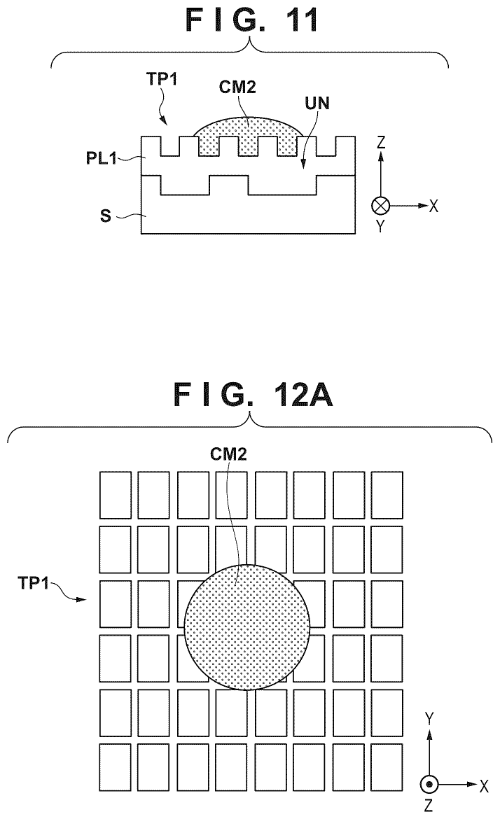

The surface of the substrate S on which the first film F1 and the second film F2 are formed may be flat, as exemplified in FIGS. 8 and 9, or may have unevenness UN, as exemplified in FIG. 11. If the surface of the substrate S on which the first film F1 and the second film F2 are formed has the unevenness UN, the first film F1 can function as a planarization film.

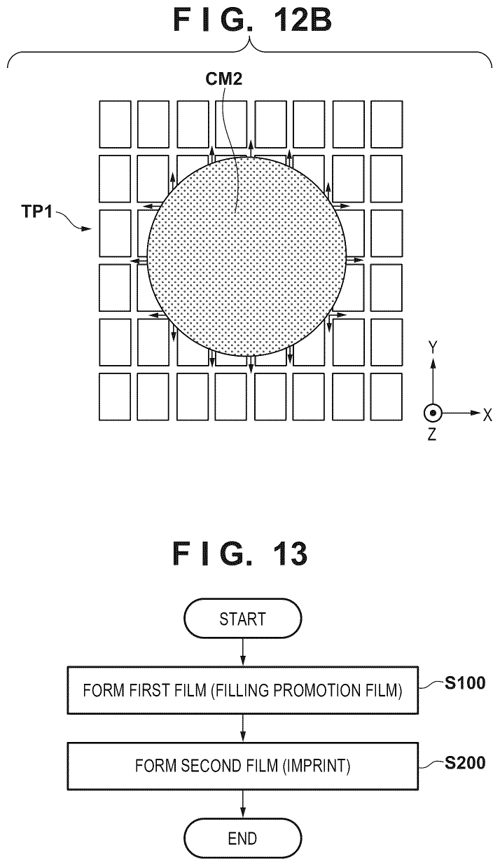

FIGS. 12A and 12B schematically show a state in which a droplet of the second curable composition CM2 arranged in the second step spreads in a case where the first transfer pattern TP1 of the first film F1 formed on the substrate S in the first step includes a rectangular grid. If the first transfer pattern TP1 includes a rectangular grid, the spread of the droplet of the second curable composition CM2 is promoted in the two directions, and thus filling of the second curable composition CM2 can also be promoted.

FIG. 13 shows the procedure of a film forming method according to the embodiment. The film forming method according to the embodiment includes first step S100 of forming the first film F1 as a filling promotion film on the substrate S, and second step S200 of forming the second film F2 on the first film F1. First step S100 is schematically shown in FIGS. 16A to 16D, and second step S200 is schematically shown in FIGS. 16E to 16H.

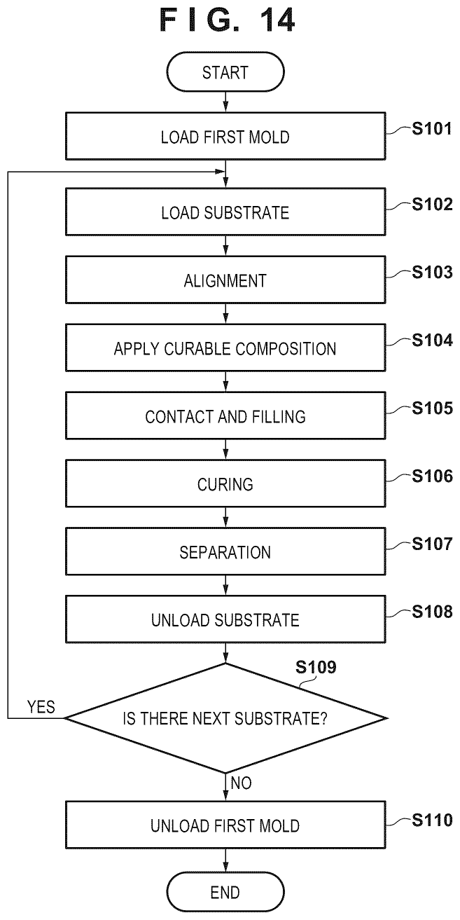

FIG. 14 shows a detailed example of first step S100. First step S100 shown in FIG. 14 can be executed by the first film forming device FFE1 and controlled by the controller CNT1. In step S101, the first mold M1 is loaded into the first film forming device FFE1, and held by the mold holder MH1. In step S102, the substrate S is loaded into the first film forming device FFE1, and held by the substrate holder SH1.

In step S103, the position of the substrate S is measured using the alignment scope AS1. In step S104, a plurality of droplets of the first curable composition CM1 are arranged, using the dispenser DU1, in a region including the plurality of shot regions of the substrate S while driving the substrate S by the substrate driving mechanism SD1.

In step S105, the mold driving mechanism MA1 and/or the substrate driving mechanism SD1 is used to bring the pattern region PS1 of the first mold M1 into contact with the plurality of droplets of the first curable composition CM1 on the substrate S. This starts filling of the first curable composition CM1 into the space between the substrate S and the pattern region PS1 of the first mold M1.

In step S106, the curing unit CU1 cures the first curable composition CM1 by giving curing energy to the first curable composition CM1 between the substrate S and the pattern region PS1 of the first mold M1, thereby forming the first film F1 as a filling promotion film. This transfers, to the first film F1, the first pattern P1 of the first mold M1 as the first transfer pattern TP1. In step S107, the mold driving mechanism MA1 and/or the substrate driving mechanism SD1 is used to separate the first mold M1 from the first film F1 on the substrate S.

In step S108, the substrate S is unloaded from the first film forming device FFE1. In step S109, it is determined whether there is the substrate S to be processed next. If there is the substrate S to be processed next, steps S102 to S108 are executed for the substrate S. On the other hand, if all the substrates S that should be processed are processed, the first mold M1 is unloaded from the first film forming device FFE1 in step S110.

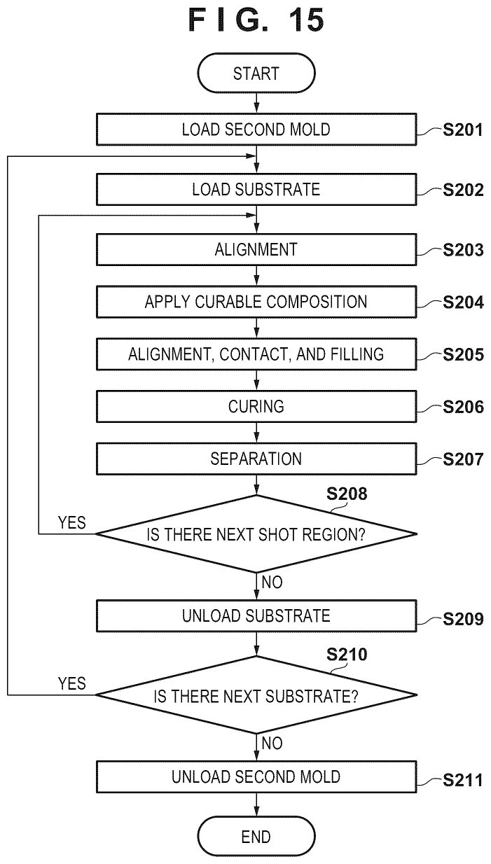

FIG. 15 shows a detailed example of second step S200. Second step S200 shown in FIG. 15 can be executed by the second film forming device FFE2 and controlled by the controller CNT2. In step S201, the second mold M2 is loaded into the second film forming device FFE2, and held by the mold holder MH2. In step S202, the substrate S on which the first film F1 has been formed as a filling promotion film is loaded into the second film forming device FFE2, and held by the substrate holder SH2.

In step S203, the positions of the plurality of shot regions SR of the substrate S are measured using the alignment scope AS2. In step S204, a plurality of droplets of the second curable composition CM2 are arranged, using the dispenser DU2, in one shot region SR selected from the plurality of shot regions of the substrate S while driving the substrate S by the substrate driving mechanism SD2. Thus, the plurality of droplets of the second curable composition CM2 start to spread. Since the first film F1 includes the first transfer pattern TP1, the spread of the plurality of droplets of the second curable composition CM2 is promoted. This promotes filling of the second curable composition CM2 into the space between the substrate S (the first film F1 thereon) and the pattern region PS2 of the second mold M2.

In step S205, the mold driving mechanism MA2 and/or the substrate driving mechanism SD2 is used to bring the pattern region PS2 of the second mold M2 into contact with the plurality of droplets of the second curable composition CM2 on the shot region SR of the substrate S. This further promotes filling of the second curable composition CM2 into the space between the substrate S (the first film F1 thereon) and the pattern region PS2 of the second mold M2. In step S205, the shot region SR and the second mold M2 may be aligned.

In step S206, the curing unit CU2 cures the second curable composition CM2 by giving curing energy to the second curable composition CM2 between the substrate S (the first film F1 thereon) and the pattern region PS2 of the second mold M2, thereby forming the second film F2. This transfers, to the second film F2, the second pattern P2 of the second mold M2 as a second transfer pattern. In step S207, the mold driving mechanism MA2 and/or the substrate driving mechanism SD2 is used to separate the second mold M2 from the second film F2 on the substrate S.

In step S208, it is determined whether there is the shot region SR to be processed next. If there is the shot region SR to be processed next, steps S203 to S207 are executed for the shot region SR. On the other hand, if all the shot regions SR that should be processed are processed, the substrate S is unloaded from the second film forming device FFE2 in step S209. In step S210, it is determined whether there is the substrate S to be processed next. If there is the substrate S to be processed next, steps S202 to S209 are executed for the substrate S. On the other hand, if all the substrates S that should be processed are processed, the second mold M2 is unloaded from the second film forming device FFE2 in step S211.

FIG. 17 shows an example of the arrangement of a pattern forming apparatus PFE for executing first step S100 and second step S200. The pattern forming apparatus PFE can include a coating device CT, a first film forming device FFU1, and a second film forming device FFU2. The coating device CT applies a curable composition onto a substrate. For example, the coating device CT can be configured to arrange a plurality of droplets of the curable composition on the substrate by an inkjet method. Alternatively, the coating device CT can be configured to arrange the curable composition on the substrate by a spin coating method.

For example, the first film forming device FFU1 shapes, using the first mold M1 having the first pattern P1, the first curable composition applied onto the substrate by the coating device CT, thereby forming the first film F1 to which the first pattern P1 has been transferred. The second film forming device FFU2 shapes, using the second mold M2 having the second pattern P2, the second curable composition applied onto the first film F1 by the coating device CT, thereby forming the second film F2 to which the second pattern P2 has been transferred. The first curable composition and the second curable composition may be the same material or materials different from each other. The first film forming device FFU1 can have, for example, an arrangement obtained by excluding the dispenser DU1 from the first film forming device FFE1. The second film forming device FFU2 can have, for example, an arrangement obtained by excluding the dispenser DU2 from the second film forming device FFE2.

The pattern forming apparatus PFE may include a rotation mechanism AT that rotates, in accordance with the direction in which the feature forming the second pattern P2 extends, the first mold M1 to be conveyed to the first film forming device FFU1. The first mold M1 can be rotated by the rotation mechanism AT so that the direction in which the first feature formed in the first film F1 by transferring the first pattern P1 crosses the direction in which the second feature of the second pattern P2 extends. The rotation mechanism AT may form a part of the alignment mechanism for aligning the substrate.

The pattern forming apparatus PFE may include load ports LP1 and LP2 on each of which a container storing the substrate is arranged, and substrate conveyance mechanisms TR1 and TR2 each of which conveys the substrate. The rotation mechanism AT or the alignment mechanism including the rotation mechanism AT can be arranged between the conveyance path of the substrate by the substrate conveyance mechanism TR1 and the conveyance path of the substrate by the substrate conveyance mechanism TR2. The pattern forming apparatus PFE can further include a controller CNT that controls the coating device CT, the first film forming device FFU1, the second film forming device FFU2, the rotation mechanism AT, the substrate conveyance mechanisms TR1 and TR2, and the like.

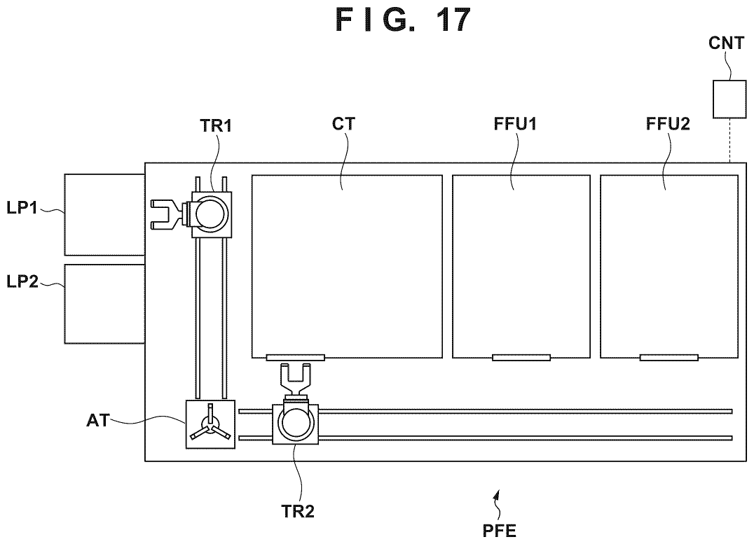

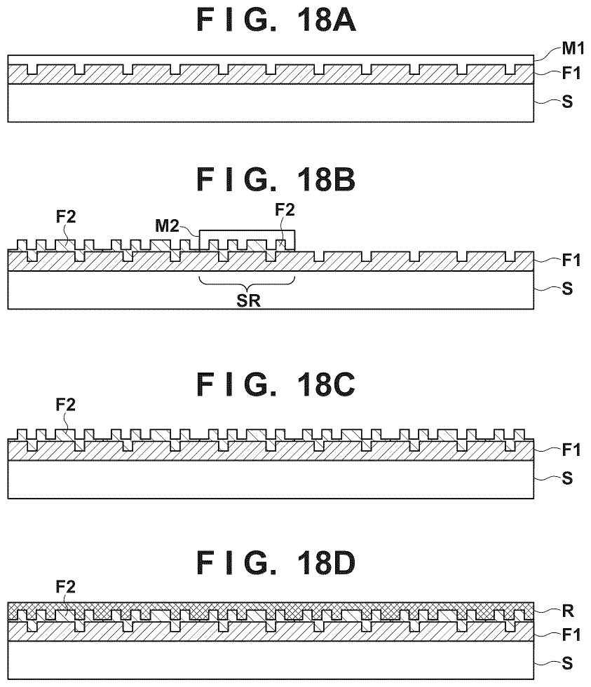

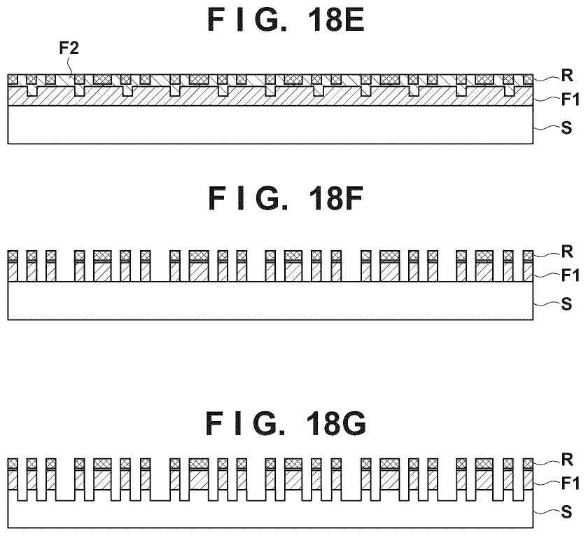

FIGS. 18A to 18G schematically show an article manufacturing method according to the embodiment. The article manufacturing method includes a step of forming the first film F1 and the second film. More specifically, in a step shown in FIG. 18A, the first film F1 to which the first pattern has been transferred is formed by arranging the first curable composition on the substrate S and shaping the first curable composition using the first mold M1 having the first pattern. In steps shown in FIGS. 18B and 18C, the second film F2 to which the second pattern has been transferred is formed by arranging the second curable composition on the first film F1 and shaping the second curable composition using the second mold M2 having the second pattern. The processing of forming the second film F2 can be performed for each shot region SR.

In a step shown in FIG. 18D, a resist film R can be formed on the second film F2. In a step shown in FIG. 18E, for example, the upper surface of the second film F2 can be exposed by etching back the resist film R.

In a step shown in FIG. 18F, the surface of the substrate S is exposed by etching the second film F2 and the first film F1 using the remaining resist film R as an etching mask. The surface of the substrate S may be, for example, the surface of a bare wafer (for example, a single-crystal silicon wafer or SOI wafer) or the surface of a substrate having at least one layer on a bare wafer.

In a step shown in FIG. 18E, the pattern is formed on the substrate S by etching the substrate S using the remaining resist film R as an etching mask.

Subsequently, an article such as a semiconductor device or a MEMS can be manufactured by executing various processes for the substrate S.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-141222, filed Aug. 22, 2024 which is hereby incorporated by reference herein in its entirety.

What is claimed is:

1. A film forming method comprising:
forming a first film to which a first pattern has been transferred by arranging a first curable composition on a substrate and shaping the first curable composition using a first mold having the first pattern; and
forming a second film to which a second pattern has been transferred by arranging a second curable composition on the first film and shaping the second curable composition using a second mold having the second pattern.

2. The method according to claim 1, wherein
the substrate includes a plurality of shot regions, and
in the forming the first film, the first pattern is collectively transferred to the first curable composition spreading to cover an entire region including the plurality of shot regions.

3. The method according to claim 2, wherein
in the forming the second film, the second pattern is transferred to the second curable composition for each shot region as a unit.

4. The method according to claim 2, wherein
the first film includes a first feature formed by transferring the first pattern, and
the second pattern includes a second feature extending in a direction crossing a direction in which the first feature extends in a state in which the second mold is arranged on the second curable composition.

5. The method according to claim 4, wherein
the second feature extends in a direction orthogonal to the direction in which the first feature extends in the state in which the second mold is arranged on the second curable composition.

6. The method according to claim 2, wherein
a plurality of grooves are formed in the first film by transferring the first pattern, and
directions in which the plurality of grooves extend coincide with radial directions in each shot region.

7. The method according to claim 6, wherein
the plurality of grooves include a groove shorter than 1/2 of a length of a short side of the shot region.

8. The method according to claim 2, wherein
a plurality of grooves are formed in the first film by transferring the first pattern, and
directions in which the plurality of grooves extend coincide with radial directions on the substrate.

9. The method according to claim 8, wherein
the plurality of grooves include a groove shorter than a radius of the substrate.

10. The method according to claim 2, wherein
the first pattern includes a plurality of regions respectively corresponding to the plurality of shot regions of the substrate, each region including a plurality of lines, and
directions in which the plurality of lines extend coincide with radial directions in each region.

11. The method according to claim 10, wherein
the plurality of lines include a line shorter than a length of a short side of each region.

12. The method according to claim 2, wherein
the first pattern includes a plurality of lines, and
directions in which the plurality of lines extend coincide with radial directions on the first mold.

13. The method according to claim 12, wherein
the plurality of lines include a line shorter than a radius of a pattern region of the first mold.

14. The method according to claim 2, wherein
the first pattern includes a rectangular grid.

15. The method according to claim 2, wherein
the first curable composition is arranged on the substrate in a form of a plurality of droplets apart from each other,
the first pattern includes a line-and-space pattern, and
a width of each of a line and a space of the line-and-space pattern is smaller than a radius of each droplet arranged on the substrate.

16. The method according to claim 2, wherein
the first pattern includes a line-and-space pattern, and
a width of each of a line and a space of the line-and-space pattern is not larger than 10 μm.

17. The method according to claim 1, wherein
the substrate undergoing the forming the first film has unevenness on a surface.

18. The method according to claim 1, wherein
the first curable composition and the second curable composition are the same material.

19. The method according to claim 1, wherein
the first curable composition and the second curable composition are materials different from each other.

20. An article manufacturing method comprising:
forming a first film to which a first pattern has been transferred by arranging a first curable composition on a substrate and shaping the first curable composition using a first mold having the first pattern; and
forming a second film to which a second pattern has been transferred by arranging a second curable composition on the first film and shaping the second curable composition using a second mold having the second pattern; and
obtaining an article by processing the substrate on which the first film and the second film have been formed.

21. A pattern forming apparatus comprising:
a coating device configured to apply a curable composition onto a substrate;
a first film forming device configured to form a first film to which a first pattern has been transferred, by shaping, using a first mold having the first pattern, the curable composition applied onto the substrate by the coating device; and
a second film forming device configured to form a second film to which a second pattern has been transferred, by shaping, using a second mold having the second pattern, the curable composition applied onto the first film of the substrate by the coating device.

22. The apparatus according to claim 21, further comprising:
a rotation mechanism configured to rotate, in accordance with a direction in which a feature forming the second pattern extends, the first mold to be conveyed to the first film forming device.
